(19) United States
(12) Patent Application Publication
(10) Pub. No.: US 2021/0286922 A1
(43) Pub. Date: Sep. 16, 2021

(54) TEST PLANNING DEVICE AND TEST PLANNING METHOD

(71) Applicant: MITSUBISHI HITACHI POWER SYSTEMS, LTD., Yokohama-shi, Kanagawa (JP)

(72) Inventors: Kazutaka Obara, Yokohama-shi (JP); Yoshinori Yamasaki, Yokohama-shi (JP); Kazuhiro Domoto, Yokohama-shi (JP); Arun Kumar Chaurasia, Yokohama-shi (JP); Hisashi Sanda, Yokohama-shi (JP); Hirotomo Hirahara, Yokohama-shi (JP); Atsushi Miyata, Yokohama-shi (JP); Keigo Matsumoto, Tokyo (JP); Hiroyoshi Kubo, Tokyo (JP); Toshihiro Baba, Yokohama-shi (JP)

(73) Assignee: MITSUBISHI HITACHI POWER SYSTEMS, LTD., Yokohama-shi, Kanagawa (JP)

(21) Appl. No.: 16/484,778

(22) PCT Filed: Feb. 5, 2018
(86) PCT No.: PCT/JP2018/003864

§ 371 Date: Aug. 8, 2019

(30) Foreign Application Priority Data
Feb. 10, 2017 (JP) 2017-023543

(51) Int. Cl. G06F 30/27; F22B 35/18

(52) U.S. Cl. CPC G06F 30/27; F22B 35/18

(57) ABSTRACT

A test planning device builds up a boiler model data by using a plurality of input parameters of the boiler classified into a plurality of parameter groups. The apparatus selects one of the plurality of parameter groups as a parameter group subjected to learning, presents test conditions in which an input parameter thereof is defined as a variable, and an input parameter of a parameter group not subjected to learning is defined as a fixed value. The device modifies the model data on the basis of the result of comparison between an actual process value and a virtual process value using the present test conditions, selects a new parameter groups subjected to learning, and presents new test conditions which use the input parameter of the test conditions in which the input parameter of the previous parameter group subjected to learning is optimal, as the fixed value.

### TECHNICAL FIELD

The present invention relates to a test planning device and a test planning method which present test conditions for model data of a power generation facility.

### BACKGROUND ART

Upon operating a boiler installed in a thermal power generation plant, it is necessary to obtain, as outputs corresponding to a result of the boiler being operated, respective output process values, for example, the concentrations of NOx and CO, and a metal temperature of each thermal conduction pipe and set many operation input parameters such that the respective output process values become optimal. There is an actual situation that since there exist in mixed form the operation input parameters which are improved and deteriorated in the output process value when changing their values, and further a variation in the output process value also changes depending on operation conditions, the operation control of the boiler is complicated.

Therefore, model data of behavior simulation may be used as part of an operation support. In terms of this point, there has been disclosed in Patent Literature 1 that operation data about the relationship between operation input parameters and output process values is used as learning data for creation of the model data.

### CITATION LIST

### Patent Literature

PATENT LITERATURE 1: Japanese Patent No. 4989421

### SUMMARY OF INVENTION

### Technical Problem

Upon newly installing a boiler and modifying equipment, a test operation is performed to acquire learning data. However, the operation input parameters are complex, and test cases become enormous when condition settings therefor are performed in multi-stages. As a result, a test period becomes long, and hence an operation start is delayed. Further, model data learning parameters are increased and hence the time and labor are required.

On the other hand, a problem arises in that when the test cases are decreased without any basis, the accuracy of behavior simulation by the model data is deteriorated, thereby resulting in no reference for the operation.

In regard to this point, in Patent Literature 1, model inputs input to a model and model outputs are divided into a plurality of groups to perform learning within a control period regardless of the number of model inputs (refer to Paragraph 0012 in the same Literature), and a method of generating model inputs of each group is made learning such that the model output of each group achieves a predetermined target value (refer to Paragraph 0013 in the same Literature). However, a problem arises in that since, at this time, the order in which the model inputs are changed among the groups is not taken into consideration, it is not possible to grasp which change in the model input exerts an influence on a change in the model output, where the model output is changed as a result of the model inputs of the plurality of groups being changed.

Further, a combustion behavior by combustion air and fuel in, for example, each combustion burner in the boiler is complex. The concentrations of NOx and CO, the surface temperature of each thermal conduction pipe, a vapor temperature, etc. may vary as respective output process values of resulting outputs on conditions of the type of the boiler, fuel to be used, and others. It is possible to create multivariable input-multivariable output model data at a stroke by using a neural network or the like. In this case, however, there is also a problem that from the viewpoint of whether the technician interfaces with experiences and physical theory, it is difficult for the technician to check it.

The present invention has been made to solve the above problems. An object of the present invention is to provide a device and a method capable of creating model data while verifying the accuracy of the model data, by learning data of less number of test cases.

### Solution to Problem

In order to achieve the above object, the present invention is a test planning device to present test conditions of a plurality of input parameters to model data of a power generation facility, which includes an input parameter presentation section to present the test conditions of the plurality of input parameters, a simulation section to compute virtual process values by applying the test conditions of the input parameters to the model data in which virtual operations of a power generation facility are regulated, an actual process value acquisition section to acquire actual process values made available by setting the test conditions of the input parameters to the power generation facility and actually operating the power generation facility, a model data learning section to perform modification processing for the model data, and an output control section to output the virtual process values and the actual process values made available through application of the test conditions, and which is characterized in that the test conditions of the input parameters are such that the plurality of input parameters are classified into a plurality of parameter groups based on a mutual relationship between each of the actual process values and each of the input parameters, the input parameter presentation section selects one parameter group subjected to learning from the plurality of parameter groups and presents the test conditions in which the input parameters of the one parameter group subjected to learning are defined as variables while the other remaining parameter groups are defined as those not subjected to learning, and in which the input parameters of the parameter groups not subjected to learning are defined as fixed values, and the model data learning section performs the modification processing for the model data using the actual process values when deviation of the actual process values and the virtual process values respectively is out of a predetermined allowable range.

The input parameters are grouped into a plurality of parameter groups in advance based on a mutual relationship of the respective input parameters. A comparison is made between the virtual process values and the actual process values using the test conditions in which the input parameters of the parameter group subjected to learning are defined as variables, and the input parameters of the parameter group not subjected to learning are defined as fixed values. Then if the deviation is within the allowable range, it is not necessary to modify the model data. If the deviation is out of the allowable range, the model data is modified. Therefore, the number of test times can be reduced as compared with the case where the number of all combinations of the input parameters is tested to find the optimum value, and the model data is modified in one attempt. Further, the smaller the deviation of the virtual process values and the actual process values, the higher the accuracy of the model data. Therefore, it becomes easy for a technician to recognize the accuracy of the model data by referring to the deviation output from the output control section and to grasp which input parameter is changed and then how the model data is changed.

Further, when a new parameter group subjected to learning is selected from the plurality of parameter groups subjected to learning, the input parameter presentation section may present new test conditions in which input parameters of the new learning parameter group are defined as variables, and the input parameters of the test condition, of the test conditions presented using the parameter group subjected to learning, in which the input parameters selected and conducted as the parameter groups subjected to learning in the past are relatively satisfactory in test result are defined as fixed values.

The above “relatively satisfactory” means that the actual process values or the virtual process values are closer to a target value (optimum value) of the process value of the power generation facility.

Thus, when the new test condition is presented while sequentially changing the parameter groups subjected to learning, the input parameters already selected as the parameter group subjected to learning are adopted with the value satisfactory in test result being defined as the fixed value. It is therefore possible to present test conditions in which the result of operation of the power generation facility is easy to be more satisfactory.

The power generation facility is a boiler, and the parameter groups are configured such that the plurality of input parameters are divided into a plurality of areas along an order in which a combustion gas of the boiler flows from a downstream side thereof to an upstream side thereof. The input parameter presentation section may select the parameter group subjected to learning along the order.

The technician becomes easier to recognize the type of the input parameters included in the same parameter group and the order of selection of the learning parameters. Further, it is possible to achieve grouping along the mutual relationship of the input parameters applied to the actual process values of the boiler.

Also, there may be further provided a learning trial number determination section to determine a learning trial number in accordance with a predetermined learning trial number determination condition based on the number of variables set to the respective input parameters included in the parameter group subjected to learning.

The above “learning trial number determination condition” may be a condition provided to calculate the number of test times regarded to have prescribed reliability or above statistically with respect to the reliability in the case where all combinations in the parameter group subjected to learning by a statistical method, for example are tried. Thus, since the learning trial number is narrowed down to a learning trial number smaller than all the combinations of the input parameters in the parameter group subjected to learning, the accuracy of the model data can efficiently be improved while further reducing the number of test times.

Further, when the deviation of the virtual process values computed by the simulation section using the actual process values and the model data subjected to the modification processing is out of the predetermined allowable range, the input parameter presentation section may change an interval between the input parameters defined as the variables of the parameter group subjected to learning, or a range of the input parameters.

When the accuracy of the model data after the modification processing is not still satisfactory, the interval between the input parameters defined as the variables of the parameter group subjected to learning or the range thereof is changed. Thus, even when the accuracy of the model data is not sufficiently obtained on the test conditions firstly presented from the input parameter presentation section, the input parameter presentation section presents a further preferable test condition to make it possible to improve the accuracy of the model data.

Further, the present invention is a test planning method to present test conditions for model data of a power generation facility, which includes a step of acquiring a plurality of input parameters classified into a plurality of parameter groups, based on a mutual relationship between actual process values made available by setting the plurality of input parameters to the power generation facility and actually operating the power generation facility and the respective input parameters, a step of presenting test conditions of a plurality of input parameters, in which the input parameters of the one selected parameter group subjected to learning, of the plurality of parameter groups are defined as variables, and the input parameters of other parameter groups not subjected to learning are defined as fixed values, a step of acquiring actual process values made available by setting the test conditions of the input parameters to the power generation facility and actually operating the power generation facility, a step of computing virtual process values by applying the test conditions of the input parameters to the model data, and a step of when deviation of the actual process values and the virtual process values is out of a predetermined allowable range, performing modification processing for the model data using the actual process values.

Thus, the number of test times can be reduced as compared with the case where the number of all combinations of the input parameters is tested to find the optimum value, and the model data is modified in one attempt. Further, the technician becomes easy to recognize the accuracy of the model data by referring to the deviation. The technician becomes easy to grasp which input parameters should be changed and then how the model data is changed.

### Advantageous Effects of Invention

According to the present invention, it is possible to provide a device and a method capable of creating model data while verifying the accuracy of the model data, by learning data of less number of test cases. Objects, configurations, and advantages other than the above will be made apparent from the description of the following embodiments.

### BRIEF DESCRIPTION OF DRAWINGS

FIG. 1 is a schematic configuration diagram illustrating a boiler;

FIG. 2 is a hardware configuration diagram of a test planning device;

FIG. 3 is a functional block diagram of the test planning device;

FIG. 4 is a flowchart illustrating a flow of the operation of the test planning device;

FIG. 5 is a flowchart illustrating a flow of the operation of the test planning device;

FIG. 6 is an explanatory diagram of grouping of input parameters;

FIG. 7 is a diagram illustrating a first setting example of test conditions;

FIG. 8 is a correlation diagram between virtual process values and actual process values;

FIG. 9 is a diagram illustrating a score conversion data example; and

FIG. 10 is a diagram illustrating a second setting example of test conditions.

### DESCRIPTION OF EMBODIMENTS

Embodiments of the present invention will hereinafter be described in detail based on the drawings. Incidentally, in all the drawings for describing the embodiments, components having the same function are denoted by the same or related reference numerals, and their repetitive description will be omitted. The present invention is not intended to be limited by the following embodiments. Further, when there are a plurality of embodiments, the present invention is intended to include even one constituted by combining the respective embodiments.

A description will hereinafter be made as to an example in which a test planning device presents test conditions for model data in which virtual operations of a boiler installed in a thermal power generation plant as a power generation facility are regulated, but the power generation facility is not limited to the boiler.

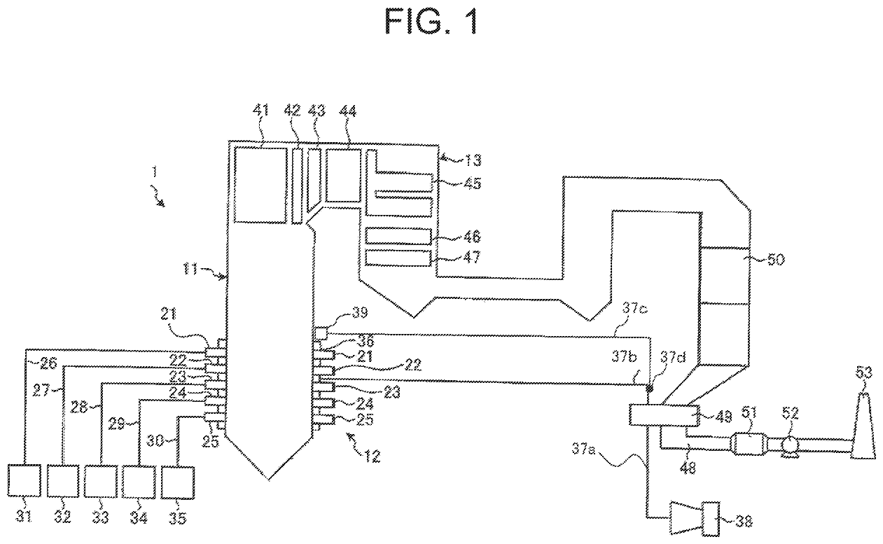

FIG. 1 is a schematic configuration diagram showing the above boiler. The boiler 1 illustrated in FIG. 1 is a coal combustion boiler which is capable of using as pulverized fuel (solid fuel), powdered coal obtained by pulverizing coal as, for example, one combusting solid fuel, combusting the powdered coal by a combustion burner in a furnace, and exchanging heat generated by the combustion with supplied water or vapor to generate vapor.

The boiler 1 has a furnace 11, a combustion device 12, and a flue 13. The furnace 11 has a hollow shape of a square cylinder, for example and is installed along a vertical direction. The furnace 11 has a wall surface which is constituted of evaporating pipes (thermal conduction pipes) and fins connecting the evaporating pipes and suppresses a rise in the temperature of a furnace wall by exchanging heat with the supplied water and vapor. Specifically, a plurality of evaporating pipes are disposed on sidewall surfaces of the furnace 11 along, for example, the vertical direction, and arranged side by side in the horizontal direction. The fin blocks between the evaporating pipe and the evaporating pipe. The furnace 11 is provided with an inclined surface at its furnace bottom and with a furnace bottom evaporating tube at the inclined surface to form a bottom surface.

The combustion device 12 is provided on the vertical lower side of the furnace wall which constitutes the furnace 11. In the present embodiment, the combustion device 12 has a plurality of combustion burners (e.g., 21, 22, 23, 24, and 25) mounted onto the furnace wall. For example, the combustion burners (burners) 21, 22, 23, 24, and 25 are arranged in plural form at equal intervals along a circumferential direction of the furnace 11. However, the shape of the furnace, the number of combustion burners at one stage, and the number of stages thereof are not limited to the present embodiment.

The respective combustion burners 21, 22, 23, 24, and 25 are respectively connected to crushers (pulverizers/mills) 31, 32, 33, 34, and 35 through pulverized coal pipes 26, 27, 28, 29, and 30. When the coals are conveyed by an unillustrated conveying system and charged into the crushers 31, 32, 33, 34, and 35, they are crushed into the size of prescribed fine powders, and the crushed coals (pulverized coals) can be supplied from the pulverized coal pipes 26, 27, 28, 29, and 30 to the combustion burners 21, 22, 23, 24, and 25 together with conveying air (primary air).

Also, the furnace 11 is provided with a wind box 36 at the mounting positions of the respective combustion burners 21, 22, 23, 24, and 25. One end of an air duct 37b is connected to the wind box 36, and the other end thereof is connected to an air duct 37a supplying air, at a connecting point 37d.

Further, the flue 13 is connected above the furnace 11 in its vertical direction, and a plurality of heat exchangers (41, 42, 43, 44, 45, 46, and 47) for producing vapor are arranged in the flue 13. Therefore, the combustion burners 21, 22, 23, 24, and 25 inject a mixture of pulverized coal fuel and combustion air into the furnace 11 to form flames and thereby produce combustion gas, after which it flows into the flue 13. Then, the supplied water or vapor flowing through the furnace wall and the heat exchangers (41 to 47) is heated by the combustion gas to generate superheated vapor. The generated superheated vapor is supplied to rotatably drive an unillustrated vapor turbine and thereby rotatably drive an unillustrated generator connected to the rotating shaft of the vapor turbine to enable power generation. Further, the flue 13 is connected with an exhaust gas duct 48 and is provided with a Selective Catalytic NOx Reduction system 50 for purifying the combustion gas, an air heater 49 which performs heat exchange between air blown from a forced draft fan 38 to the air duct 37a and exhaust gas blown through the exhaust gas duct 48, a soot and electric dust precipitator 51, an induction draft fan 52, etc. are provided with a stack 53 at its downstream end.

The furnace 11 is a so-called two-stage combustion type furnace which after fuel excessive combustion by the conveying air (primary air) for the powdered coal and the combustion air (secondary air) charged from the wind box 36 to the furnace 11, newly charges combustion air (additional air) to perform fuel lean combustion. Therefore, the furnace 11 is provided with an additional air port 39. One end of the air duct 37c is connected to the additional air port 39, and the other end thereof is connected to the air duct 37a supplying air at the connecting point 37d.

The air blown from the forced draft fan 38 to the air duct 37a is warmed by the combustion gas and the heat exchange with the air heater 49 and branched, at the connecting point 37d, into the secondary air introduced into the wind box 36 via the air duct 37b and the additional air introduced into the additional air port 39 via the air duct 37c.

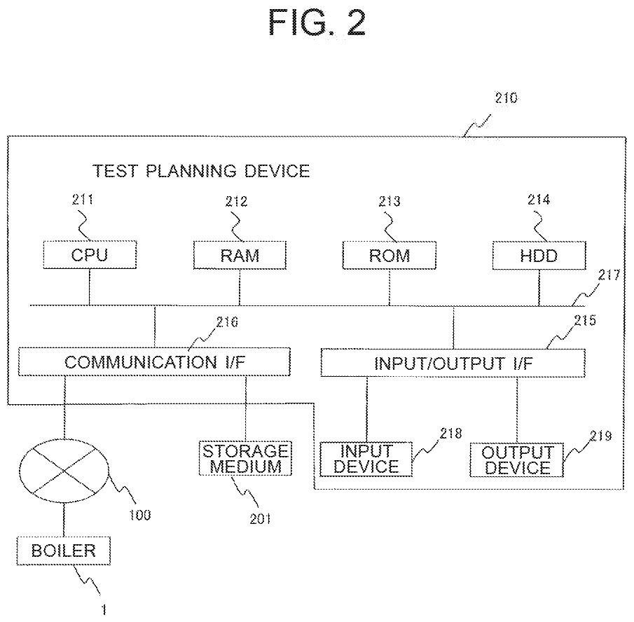

FIG. 2 is a hardware configuration diagram of a test planning device 210. The test planning device 210 includes a CPU (Central Processing Unit) 211, a RAM (Random Access Memory) 212, a ROM (Read Only Memory) 213, an HDD (Hard Disk Drive) 214, an input/output interface (I/F) 215, and a communication interface (I/F) 216 and configured to connect these to each other via a bus 217. An input device 218 such as a keyboard or the like, and an output device 219 such as a display or a printer or the like are respectively connected to the input/output interface (I/F) 215. Further, the communication I/F 216 of the test planning device 210 and the boiler 1 may be connected via a network 100 and is connected to a storage medium 201, e.g., a memory card to acquire actual process values to be described later. Incidentally, the hardware configuration of the test planning device 210 is not limited to the above, but may be configured by a combination of a control circuit and a storage device.

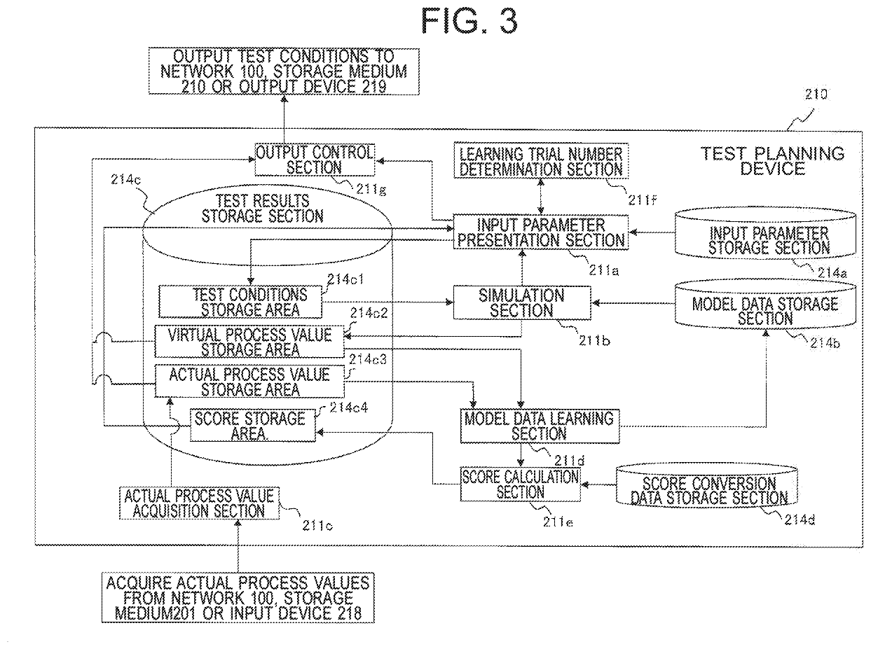

FIG. 3 is a functional block diagram of the test planning device 210. The test planning device 210 includes an input parameter presentation section 211a, a simulation section 211b, an actual process value acquisition section 211c, a model data learning section 211d, a score calculation section 211e, a learning trial number determination section 211f, and an output control section 211g. These respective components may be configured such that the CPU 211 loads software achieving respective functions prestored in the ROM 213 and HDD 214 onto the RAM 212 and executes the same to thereby make the cooperation of the software and hardware, or may be configured by the control circuit which realizes each function. Further, the test planning device 210 includes an input parameter storage section 214a, a model data storage section 214b, a test results storage section 214c, and a score conversion data storage section 214d. The test results storage section 214c includes a test conditions storage area 214c1, a virtual process value storage area 214c2, an actual process value storage area 214c3, and a score storage area 214c4. The respective storage areas are configured to be associated with each other. The above respective storage sections and storage areas may be configured in a partial area of the RAM 212, ROM 213 or HDD 214.

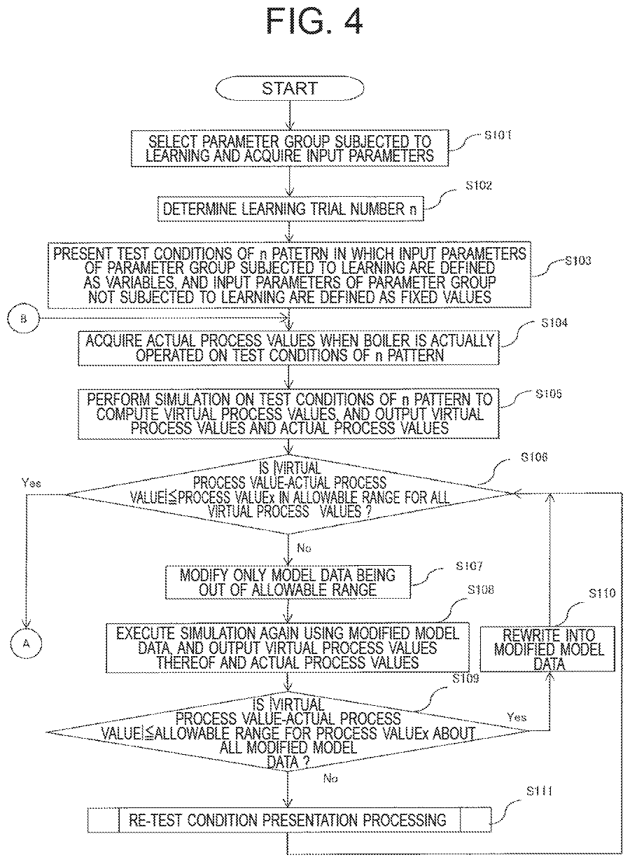

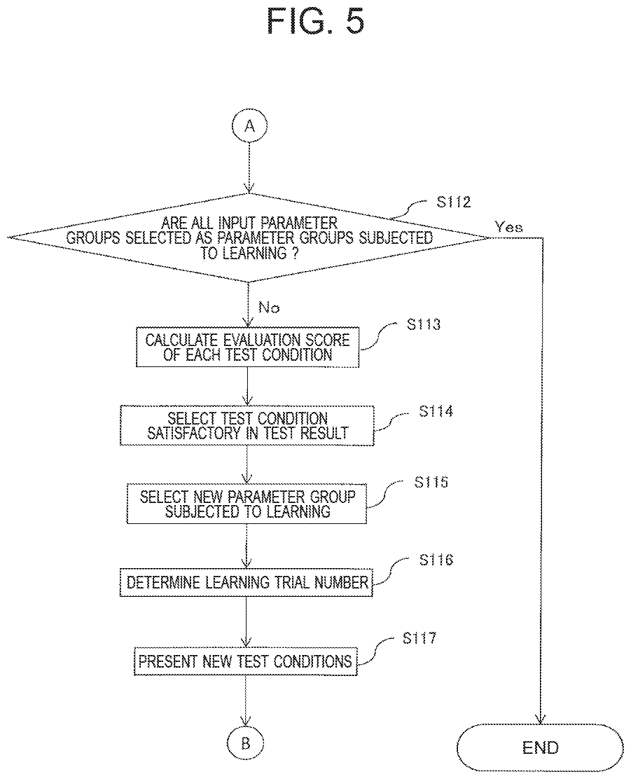

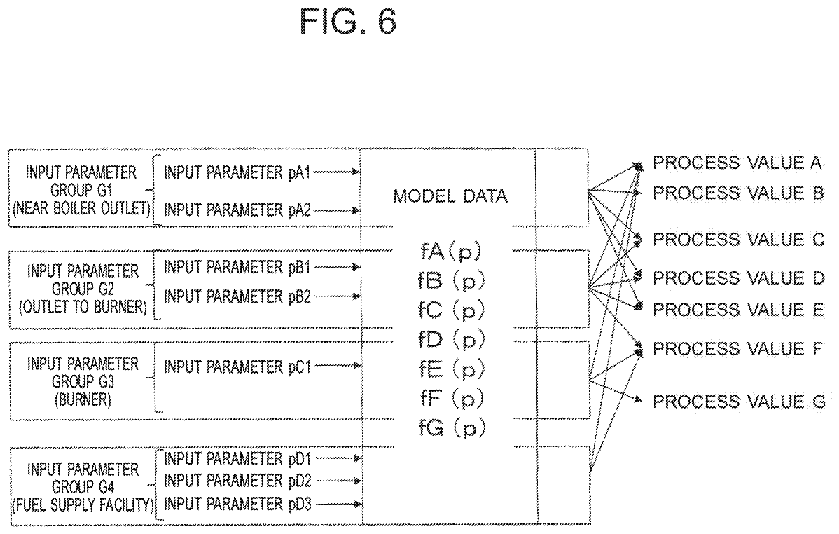

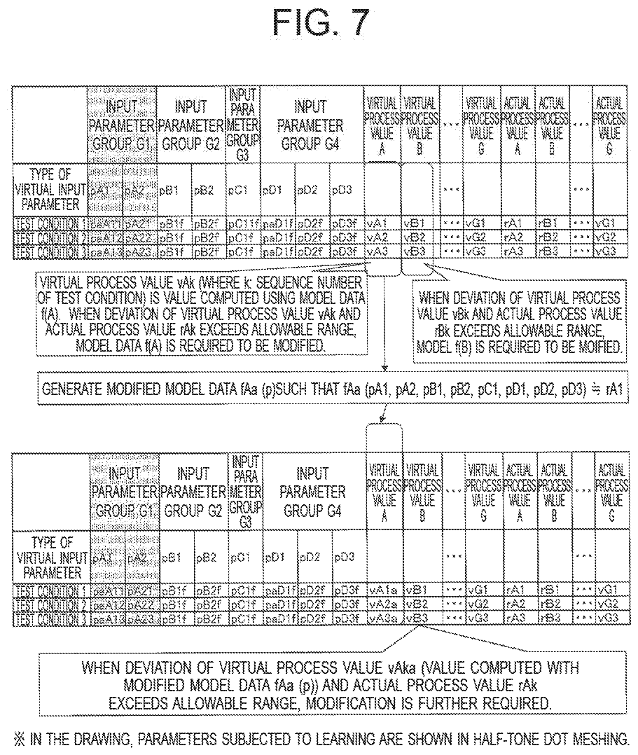

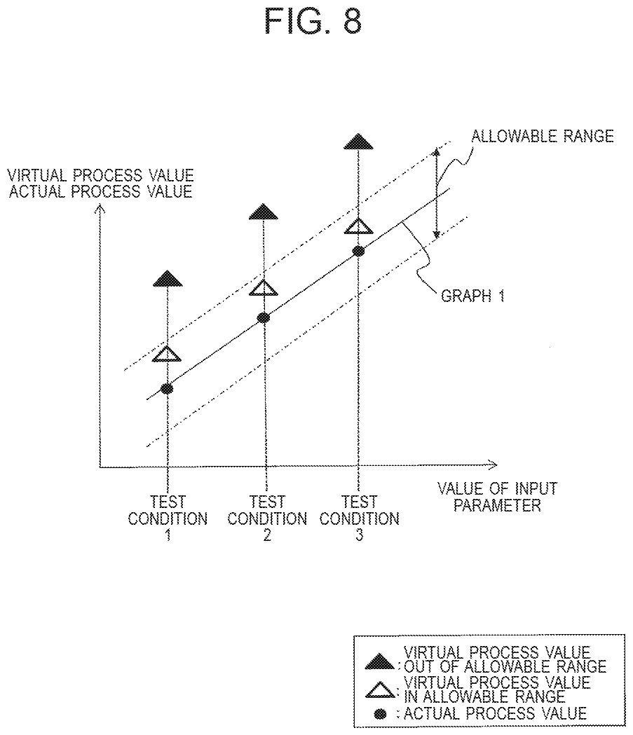

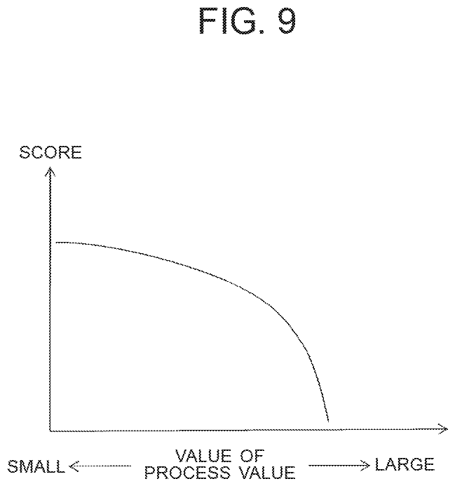

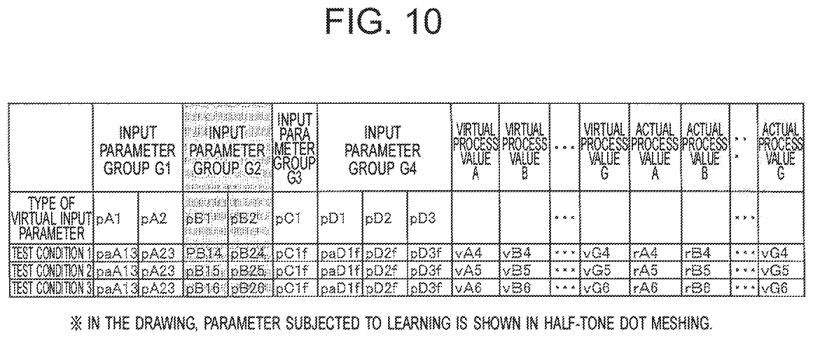

A description will be made as to the operation of the test planning device 210 with reference to FIGS. 4 to 10. FIGS. 4 and 5 are flowcharts showing the flow of the operation of the test planning device 210. FIG. 6 is an explanatory of grouping of input parameters. Incidentally, in FIG. 6, virtual process values and actual process values are described simply as process values without distinguishing them from each other. FIG. 7 is a diagram showing a first setting example of test conditions. FIG. 8 is a correlation diagram between virtual process values and actual process values. FIG. 9 is a diagram illustrating a score conversion data example. FIG. 10 is a diagram illustrating a second setting example of test conditions.

Prior to the following processing, input parameters used for simulation are grouped in advance into a plurality of parameter groups based on a mutual relationship between each of the process values and each of the input parameters and stored in the test conditions storage area 214c1 shown in FIG. 3.

In the present embodiment, the mutual relationship with the input parameters takes into consideration an influence on the process values. Further, the positions (the position of a device related to each input parameter, the position of an influence range where the input parameter is changed, etc.) of the input parameters in the boiler are also taken into consideration. For example, in the present embodiment, the input parameters in which the mutual relationship with the respective input parameters exerts less influence on the process values are assumed to be parameter groups subjected to grouping in plural form in advance. Then, the parameter groups are configured such that a plurality of input parameters are divided into plural areas along an order in which the combustion gas of the boiler 1 flows from the downstream side of the combustion gas to its upstream side. The process values in the area on the downstream side of the combustion gas in which the result has been determined to be one layer are sequentially divided into the areas on the upstream side of the combustion gas in which the result is to be determined from this time, so that grouping along the mutual relationship of the input parameters can be achieved. It is therefore possible to improve the accuracy of the process values made available from the grouped parameter groups. Thus, in the present embodiment, as shown in FIG. 6, the input parameters are divided into a plurality of areas, e.g., an input parameter group G1 includes values pA1 and pA2 of input parameters near a boiler outlet (e.g., from the outlet of the furnace 11 to the vicinity of the heat exchanger 41). Further, an input parameter group G2 includes values pB1 and pB2 of input parameters from the boiler outlet to the burner (e.g., from the outlet of the furnace 11 to the vicinity of the combustion burner 21), an input parameter group G3 includes a value pC1 of an input parameter of the burner (near the combustion burners 21, 22, 23, 24, and 25, for example). An input parameter group G4 includes values pD1, pD2, and pD3 of input parameters related to a fuel supply facility (near the crushers 31, 32, 33, 34, and 35, for example).

Seven model data fA (p), fB (p), fC (p), fD (p), fE (p), fF (p), and fG (p) for calculating seven types of virtual process values vA, vB, vC, vD, vE, VF, and vG (described simply as a process value A, a process value B, . . . , and a process value G without distinguishing between the virtual process values and the actual process values in FIG. 6) are stored in the model data storage section 214b.

The values pA1, pA2, pB1, pB2, pC1, pD1, pD2, and pD3 of all the input parameters are applied to the model data fA (p), fB (p), fC (p), fD (p), fE (p), fF (p), and fG (p) to calculate the seven virtual process values VA, vB, vC, vD, vE, vF, and vG.

Here, the respective input parameters include those having a strong relationship relatively (high in terms of the response of each input parameter to each actual process value, the rate of change in value, etc.) and those having a low relationship relatively (low in terms of the response of each input parameter to each actual process value, the rate of change in value, etc.) and are grouped into a plurality of parameter groups based on the mutual relationship. As a result of the input parameters being grouped in order from the above combustion gas, the input parameter group G1 forms the set of the values pA1 and pA2 of the input parameters which are relatively high in terms of the response to actual process values rA, rB, rC, rD, and rE (described simply as the process value A, process value B, . . . , and process value G without distinguishing between the virtual process values and the actual process values in FIG. 6), the rate of change in the value, etc., and which have a strong relationship relatively. Likewise, the input parameter group G2 forms the set of the values pB1 and pB2 of the input parameters having a strong relationship relatively to the actual process values rA, rC, rD, rE, and rF. The input parameter group G3 is formed to include the value pC1 of the input parameter having a strong relationship relatively to the actual process values rA, rF, and rG. The input parameter group G4 is formed as the set including the values pD1, pD2, and pD3 of the input parameters having a strong relationship relatively to the actual process values rA and rF.

As specific examples of the above input parameters, there are in the case of the boiler 1, a supply amount of the combustion air, a burner angle, the operating number of the fuel supply facilities, and a valve aperture of the after air port (a supply amount of after air). A specific examples of the process values, there are an environment load quantity (concentrations of NOx and CO), installation efficiency, a part temperature, a vapor temperature, a metal temperature of the thermal conduction pipe, etc.

Referring back to FIG. 4, a description will be made as to a flowchart showing the flow of the operation of the test planning device 210. First, the input parameter presentation section 211a determines one of a plurality of parameter groups as a parameter group being subjected to learning by referring to the test conditions storage area 214c1, and determines those other than that as parameter groups being not subjected to learning to acquire respective input parameters (S101). In the example of the present embodiment in particular, the input parameter presentation section 211a selects the parameter group being subjected to learning along an order in which the combustion gas flows from the area on the downstream side of the combustion gas to the area on the upstream side thereof. Thus, as illustrated in the example of FIG. 7 as the first test condition presentation, the parameter group being subjected to learning is determined as an input parameter group G1, and parameter groups being not subjected to learning are determined as input parameter groups G2, G3, and G4.

The learning trial number determination section 211f determines a learning trial number n on the basis of the number of types of the input parameters contained in the parameter group being subjected to learning, and the number of variables of the respective input parameters (S102). Since in the example of FIG. 7, the number of types of variables of the input parameter group G1 is two of pA1 and pA2, and the number of variables are three of test conditions 1, 2, and 3, it is necessary to perform simulation under test conditions of 9 patterns in the form of 3² (3×3) when the test for the combinations of all variables in G1 is intended to be performed. Thus, the learning trial number determination section 211f determines a leaning trial number n smaller than a trial number covering the combinations of all the variables in accordance with a leaning trial number determination condition determined in advance by using a statistical technique. In the present example, n=3.

The input parameter presentation section 211a determines test conditions used for the tests of n times determined by the learning trial number determination section 211f, i.e., respective input parameters of n patterns and presents the test conditions (S103). In the present example, in all of test conditions 1 to 3 of 3 patterns, the parameter of the input parameter group G1 is defined as a variable, and the parameters of the input parameter groups G2, G3, and G4 are defined as fixed values. As the fixed values, the standard values or design values of the respective input parameters, and the values expected to be the optimum values may be used.

The input parameter presentation section 211a stores the presented test conditions of n patterns in the test conditions storage area 214cl and outputs the same to the output control section 211g.

On the test conditions of n patterns output from the output control section 211g, a trial operation is actually performed in the boiler 1 to obtain actual process values rAk to rGk (where k=1 to n). The actual process value acquisition section 211c acquires the actual process values rAk to rGk via the network 100, the storage medium 201 or the input device 218 (S104) and stores the same in the actual process value storage area 214c3.

The simulation section 211b reads the respective test conditions from the test conditions storage area 214cl and applies the test conditions to the model data fA (p), fB (p) and fG (p) provided to compute the respective virtual process values vAk to vGk to thereby compute respective virtual process values vAk to vGk. Then, the output control section 211g outputs the test conditions, and the virtual process values and the actual process values where the test conditions are applied thereto (S105).

The model data fA (p), fB (p) . . . , and fG (p) determined according to the types of the virtual process values vA to vG are stored in the model data storage section 214b by the same number as the number of types of the virtual process values. The simulation section 211b sequentially applies the test conditions k (pA1k, pA2k, pB1k, pB2k, pC1k, pD1k, pD2k, and pD3k) to the respective model data to calculate the respective virtual process values vAk to vGk of the test conditions k from the following equation (1):

$$\begin{matrix}vAK = fA ( p A 1 k , p A 2 k , p B 1 k , p B 2 k . p C 1 k , p D 1 k , p D 2 k , pD 3 k ) \\ vBk = fB ( p A 1 k , p A 2 k , p B 1 k , p B 2 k . p C 1 k , p D 1 k , p D 2 k , pD 3 k ) \\ vCk = fC ( p A 1 k , p A 2 k , p B 1 k , p B 2 k . p C 1 k , p D 1 k , p D 2 k , pD 3 k ) \\ vDk = fD ( p A 1 k , p A 2 k , p B 1 k , p B 2 k . p C 1 k , p D 1 k , p D 2 k , pD 3 k ) \\ vEk = fE ( p A 1 k , p A 2 k , p B 1 k , p B 2 k . p C 1 k , p D 1 k , p D 2 k , pD 3 k ) \\ vFk = fF ( p A 1 k , p A 2 k , p B 1 k , p B 2 k . p C 1 k , p D 1 k , p D 2 k , pD 3 k ) \\ vGk = fG ( p A 1 k , p A 2 k , p B 1 k , p B 2 k . p C 1 k , p D 1 k , p D 2 k , pD 3 k )\end{matrix} \} ( 1 ) \qquad [ Equation 1 ]$$

In the equation (1), under the test conditions 1 to 3, pA1k and pA2k are variables, and pB1k, pB2k, pC1k, pD1k, pD2k, and pD3k are fixed values.

The model data learning section 211d compares the virtual process values and the actual process values every types of the process values and determines whether deviation (the absolute value of the difference between the virtual process value and the actual process value) of the virtual process values and the actual process values is in a predetermined allowable range (hereinafter abbreviated as “allowable range”) determined as a predetermined value in advance with respect to all the process values (S106). If even one model data which is out of the allowable range is present (S106/No), only the model data out of the allowable range is modified to generate the modified model data (S107). In the example of FIG. 7, the modified model data fAa (p) is generated.

FIG. 8 is a correlation diagram between the virtual process values and the actual process values. A graph 1 is a graph (by the least squared method, for example) created on the basis of points at which the actual process values, e.g., rA1, rA2, and rA3 obtained by performing the trial operation by the boiler 1 according to the test conditions 1, 2, and 3 are plotted. An allowable range used to make a determination as to the necessity of the modification of the model data fA (p) is provided centering on the graph. Then, if the virtual process values are included in the allowable range, it is not necessary to modify the model data fA (p). If not so, then the model data learning section 211d modifies the model data fA (p) such that the actual process value rA1 is obtained with respect to each input parameter, and thereby generates modified model data fAa (p). It is determined according to a procedure similar to that of the model data fA (p) whether other model data are also required to be modified. In the case of the necessity thereof, they are modified.

The model data learning section 211d executes simulation processing again by using the modified model data to compute post-modification virtual process values. The output control section 211g outputs test conditions applied to the modified model data, and the virtual process values and actual process values at that time (S108). In the example of FIG. 7, the test conditions 1 to 3 are applied to the modified model data fAa (p) to calculate virtual process values vA1a, vA2a, and vA3a again. If deviation of the virtual process values vA1a, vA2a, and vA3a and the actual process values rA, rB, and rC falls in the allowable range (S109/Yes), the modification is determined to have been suitably done, and the model data fA (p) stored in the model data storage section 214b is rewritten into the modified model data fAa (p) (S110). The processing is returned to Step S106.

If the virtual process values obtained by the modified model data, e.g., the above virtual process values vA1a, vA2a, and vA3a do not fall in the allowable range of the actual process values rA, rB, and rC (S109/No), re-test condition presentation processing is executed (S111).

In the re-test condition presentation processing (S111), when the deviation of the actual process values and the virtual process values computed by the simulation section 211b using the modified model data is out of the predetermined allowable range, the input parameter presentation section 211a changes the interval between the input parameters set as the variables of the parameter group being subjected to learning or the range of the input parameters and presents test conditions again. Then, Steps S104 to S111 are executed using the test conditions presented again. Thereafter, the operation returns to Step S106.

If the deviation of all the virtual process values and the actual process values corresponding thereto falls within the allowable range (S106/Yes), the model data learning section 211d does not require the modification of model data. Thus, as shown in FIG. 5, the input parameter presentation section 211a determines whether the input parameter groups each unselected as the parameter group being subjected to learning remain (S112). If the input parameter groups remain, the input parameter presentation section 211a starts presentation processing of test conditions using a new parameter group being subjected to learning (S112/No).

Thus, the score calculation section 211e calculates evaluation scores of the test conditions 1 to k using the parameter group being subjected to learning selected in Step S101 by using score conversion data set to the score conversion data storage section 214d in advance (refer to FIG. 9) and stores the same in the score storage area 214c4 (S113).

FIG. 9 is a diagram illustrating one example of the score conversion data. Each actual process value is defined such that the value of the score becomes small as it becomes far from a prescribed object. In terms of the characteristic of each actual process value, there is illustrated, for example, one in which the value of the score increases as the process value becomes smaller. The score conversion data corresponding to the respective types of the respective actual process values rA to rG are stored in the score conversion data storage section 214d. The score calculation section 211e reads the actual process value rA1 and calculates the score corresponding to the actual process value rA1 by using the score conversion data corresponding to the actual process value rA1. Likewise, the score calculation section 211e calculates the scores corresponding to all actual process values rB1 to rG1. Then, the whole score of the test condition 1 is calculated by using the totaled value of scores calculated based on the respective process values obtained under the test condition 1. Likewise, the whole scores of the test conditions 2 and 3 are also calculated.

Although the whole score of each test condition is calculated by using the actual process values in the above, scoring is performed on the virtual process values if the deviation of the virtual process values and the actual process values falls within the allowable range, and the whole score of each test condition may be calculated.

The input parameter presentation section 211a refers to the evaluation score stored in the score storage area 214c4 and selects one or more test conditions relatively satisfactory in test result, preferably, the most excellent one with being closer to a predetermined target value (optimum value) of the actual process value (S114).

The input parameter presentation section 211a selects a next new parameter group being subjected to learning, e.g., the input parameter group G2 (S115). The learning trial number determination section 211f newly determines a learning trial number n on the basis of the number of types of the input parameters included in the input parameter group G2 and the number of variables thereof (S116).

The input parameter presentation section 211a presents a new test condition consisting of a pattern number of the same number as the newly-determined learning trial number n (S117).

In the present Step, the input parameters of the newly-selected parameter group being subjected to learning are defined as variables. The input parameters (e.g., input parameter group G1) of the input parameter group already selected as the parameter group being subjected to learning make use of input parameters of a test condition selected as being closest to the optimum condition closer to the predetermined target value (optimum value) of the actual process value, based on the evaluation score calculated using the score conversion data set in advance. In the example of FIG. 10, the test condition is defined as a second setting, the new parameter group being subjected to learning is defined as the input parameter group G2, the values pB1k and pB2k of the input parameters are assumed to be variables. The input parameters of the input parameter group G1 being one of the parameter groups being not subjected to learning are defined as the values pA13 and pA23 of the input parameters of the test condition 3 determined to be the optimum condition, and the values of the input parameters of the input parameter groups G3 and G4 are assumed to be fixed values pC1f, pD1f, and pD2f.

When all the input parameter groups are selected and finished as the parameter groups being subjected to learning (S112/Yes), a series of processing is terminated.

There are, for example, many input parameters more than 10 items, which are used for the operation of the boiler installed in the thermal power generation plant as the power generation facility. There are also many process values. Further, when a certain input parameter is changed, a process value which becomes satisfactory and a process value which is deteriorated coexist with each other, and hence operation control is complicated. Therefore, as part of an operation support, model data regulating the virtual operation of the boiler is configured, and simulation using the model data may be performed. In order to improve the accuracy of the simulation, there is a demand that one desires to suitably set the test conditions in terms of the viewpoint that when setting input parameters in multiple stages and performing a test operation, the time for the trial operation is taken long as the test conditions to be tried increase, whereas when the test conditions are reduced without any basis, the accuracy of the model data is deteriorated.

According to the present embodiment, the input parameters are grouped into a plurality of parameter groups in advance, based on the mutual relationship between the respective input parameters. For example, the input parameters in which the mutual relationship of the respective input parameters exerts less influence on the process values are grouped into a plurality of input parameter groups in advance. The model data is first modified on the basis of comparison between each virtual process value and each actual process value using a test condition in which input parameters of a parameter group being subjected to learning are defined as variables, and input parameters of a parameter group being not subjected to learning are defined as fixed values. Thus, if the optimum value is found, it is used as the fixed value, and the model data is modified while sequentially changing the parameter groups subjected to learning. Therefore, the number of test times can be reduced compared with the case where the number of all combinations of the input parameters is tested without grouping the input parameters in advance to find the optimum value, and the model data is modified in one attempt. By outputting the actual process values and the virtual process values together with the test conditions, it is easy for a technician to grasp which input parameters should be changed and then how the model data is changed. Further, it becomes easy for the technician to grasp the accuracy of model data on the basis of the magnitude of deviation of each actual process value and each virtual process value.

Further, a plurality of input parameters are divided into a plurality of areas along an order in which a combustion gas of the boiler flows from a downstream side of the combustion gas to its upstream side. With the selection of each parameter group subjected to learning along this order, the technician becomes easy to more recognize the type of the input parameters included in the same parameter group. Further, since the grouping along the mutual relationship of the input parameters applied to the actual process values of the boiler can be realized, the accuracy of the process values obtained from the parameter groups subjected to the grouping is improved.

Further, since the learning trial number determination section 211f makes narrowing down to the learning trial number (e.g., three times) smaller than all combinations (e.g., 3²=9 patterns) of the input parameters in the parameter groups subjected to learning, the accuracy of model data can be improved efficiently while achieving a further reduction in the number of test times in addition to the reduction in the number of test times by the effect of grouping of the input parameters.

Since, in the case where the accuracy of the modified model data is insufficient, the input parameter presentation section 211a changes the interval between the input parameters assumed to be the variables of the parameter groups subjected to learning or the range of the input parameters, and presents a new test condition, it is possible to improve a failure in the accuracy of the modified model data.

The above embodiment is not intended to limit the present invention, and various modifications which do not depart from the spirit of the present invention are included in the present embodiment. For example, in Steps S104 and S105 of FIG. 4, the sequence of the acquisition of the actual process values and the computation of the virtual process values may be exchanged. Also, in Step S105 and Step S108, without performing the acquisition of the actual process values and the output of the virtual process values to the technician, they may be changed to, for example, the form of acquiring the actual process values and outputting the virtual process values to the model data learning section inside the test planning device. Further, the calculation of each evaluation score by the score calculation section 211e is a mere extraction example of a condition satisfactory in the test result. A satisfactory test condition may be extracted using the actual values of the actual process value and the virtual process value without using the scores.

Further, the present invention may be applied to learning of model data of an operation facility different from the boiler as a power generation facility.

In addition, the input parameter presentation section 211a may be configured such that the presented test condition is output from the output control section 211g to the output device 219 and the technician is able to visually recognize test conditions presented at any time. Moreover, the input parameter presentation section 211a may be configured such that the technician is able to perform a modification operation on the presented test condition through the input device 218.

### REFERENCE SIGNS LIST

1: boiler,
100: network,
210: test planning device,
211a: input parameter presentation section,
211b: simulation section,
211c: actual process value acquisition section,
211d: model data learning section,
211e: score calculation section,
211f: learning trial number determination section,
214a: input parameter storage section,
214b: model data storage section,
214c: test results storage section,
214d: score conversion data storage section.

1-6. (canceled)

7. A test planning device to present test conditions of a plurality of input parameters for model data of a boiler comprising:
an input parameter presentation section to present the test conditions of the plurality of input parameters;
a simulation section to compute virtual process values by applying the test conditions of the input parameters to the model data in which virtual operations of the boiler are simulated;
an actual process value acquisition section to acquire actual process values made available by setting the test conditions of the input parameters to the boiler and actually operating the boiler;
a model data learning section to perform modification processing for the model data; and
an output control section to output the virtual process values and the actual process values made available through application of the test conditions,
wherein the test conditions of the input parameters are such that the plurality of input parameters are classified into a plurality of parameter groups based on a mutual relationship between each of the actual process values and each of the input parameters,
the parameter groups are configured such that the plurality of input parameters are divided into a plurality of areas along an order in which a combustion gas of the boiler flows from a downstream side to an upstream side,
the input parameter presentation section selects one parameter group subjected to learning from the plurality of parameter groups along the order and presents the test conditions in which the input parameters of the one parameter group subjected to learning are defined as variables while the other remaining parameter groups are defined as those not subjected to learning, and in which the input parameters of the parameter groups not subjected to learning are defined as fixed values, and
the model data learning section performs the modification processing for the model data based on the actual process values when deviation of the actual process values and the virtual process values respectively is out of a predetermined allowable range.

8. The test planning device according to claim 7, wherein when the input parameter presentation section selects a new parameter group subjected to learning from the plurality of parameter groups subjected to learning, it presents new test conditions in which input parameters of the new learning parameter group are defined as variables, and the input parameters of the test condition, of the test conditions presented using the parameter group subjected to learning, in which the input parameters selected and conducted as the parameter groups subjected to learning in the past are relatively satisfactory in test result are defined as fixed values.

9. The test planning device according to claim 7, further comprising a learning trial number determination section to determine a learning trial number in accordance with a predetermined learning trial number determination condition based on the number of variables set to the respective input parameters included in the parameter group subjected to learning.

10. The test planning device according to claim 7, wherein when the deviation of the actual process values and the virtual process values computed by the simulation section using the model data subjected to the modification processing is out of the predetermined allowable range, the input parameter presentation section changes an interval between the input parameters defined as the variables of the parameter group subjected to learning, or a range of the input parameters.

11. A test planning method to present test conditions of a plurality of input parameters to model data in which virtual operations of a boiler are simulated, comprising:
a step of acquiring a plurality of input parameters classified into a plurality of parameter groups which are configured such that the plurality of input parameters are divided into a plurality of areas along an order in which a combustion gas of the boiler flows from a downstream side to an upstream side, based on a mutual relationship between actual process values made available by setting the plurality of input parameters to the boiler and actually operating the boiler and the respective input parameters;
a step of presenting test conditions of a plurality of input parameters of a parameter group subjected to learning, which is the one parameter group selected among the plurality of parameter groups along the order, are defined as variables, and the input parameters of other parameter groups not subjected to learning are defined as fixed values;
a step of acquiring actual process values made available by setting the test conditions of the input parameters to the boiler and actually operating the boiler;
a step of computing virtual process values by applying the test conditions of the input parameters to the model data;
a step of when deviation of the actual process values and the virtual process values is out of a predetermined allowable range, performing modification processing for the model data using the actual process values; and
a step of outputting the actual process and the virtual process values made available by applying the test conditions to the modified model data.
